(19) United States
(12) Patent Application Publication
(10) Pub. No.: US 2018/0068872 A1
(43) Pub. Date: Mar. 8, 2018

(54) Carrier Substrate For Semiconductor Structures Suitable For A Transfer By Transfer Print And Manufacturing Of The Semiconductor Structures On The Carrier Substrate

(71) Applicant: X-FAB SEMICONDUCTOR FOUNDRIES AG, Erfurt (DE)

(72) Inventor: Ralf Lerner, Erfurt (DE)

(21) Appl. No.: 15/648,728

(22) Filed: Jul. 13, 2017

(30) Foreign Application Priority Data
Jul. 17, 2016 (DE) DE102016113151.2
Sep. 9, 2016 (DE) DE102016117030.5

(51) Int. Cl. H01L 21/673; H01L 21/02; H01L 21/20

(52) U.S. Cl. CPC H01L 21/673; H01L 21/20; H01L 21/02019

(57) ABSTRACT

A carrier substrate for semiconductor structures which can be transferred by transfer printing, and manufacture of the semiconductor structures on the carrier substrate. The number of the required process steps and thus the required effort is to be generally reduced in the manufacture of component structures on a carrier substrate for providing the component structures in a state in which they can be transferred to a further substrate by transfer printing. For this purpose, it is suggested to produce semiconductor structures to be transferred on a carrier substrate. The method comprises providing a carrier substrate (10) including a semiconductor material with a selected crystal orientation. An active region (11) is produced which has an exposed semiconductor surface (11) and is almost completely delimited by dielectric regions (30, 80) including an isolating dielectric material. Forming a semiconductor structure (40) to be transferred by depositing at least one semiconductor layer on the active region (11) is provided. Removal of at least a part or portion of the dielectric material is performed as well as an etching and removal of semiconductor material beneath the semiconductor structure (40).

### FIELD OF INVENTION

These inventions relate generally to the manufacture of integrated circuits, wherein one or more components produced on a carrier substrate or donor substrate are transferred for obtaining or providing different component properties on the receiving integrated circuit which would not, or only with great efforts, be achievable by process technologies applied for the manufacture thereof.

In today's process technologies for the manufacture of integrated circuits, a great number of components are produced in and on a substrate by applying specific process technologies. In recent developments, for enhancing component properties and/or process technologies, components are produced on a carrier substrate by applying different process technologies and/or process materials, and are then transferred to the integrated circuit (i.e. to a receiving substrate), this being performed as a so-called printing process or transfer printing. For example, a component produced, for instance, on the basis of GaN, for example, in the form of a fast transistor is transferred to a CMOS environment in order to thus impart properties to the underlying CMOS circuit which cannot, or only with very great efforts, be obtained otherwise.

By transfer printing, semiconductor components can be released from a first semiconductor wafer and transferred to a second semiconductor wafer by use of a stamp and printed thereon.

### BACKGROUND INFORMATION

US 2009/0294803 A1, DE 11 2011 101 135 T5 and U.S. Pat. No. 8,664,699 B2 describe the method of transfer printing in which semiconductor components can be transferred from a first semiconductor wafer to a new substrate by use of a stamp made of elastomeric material. This second substrate may, for example, also be a second semiconductor wafer. The components to be transferred are initially masked and etched free at the sides. In this etching step, etching is performed around the component except for small so-called connection elements which can be fractured. In a next etching step, etching is performed beneath the component, wherein the component is mechanically retained by said connection elements only. A part of the components is brought into conformal contact with the surface of the stamp and released from the first semiconductor wafer by adhesion to the stamp, i.e. the connection elements are fractured in this process. Then, the components adhering to the stamp are brought into conformal contact with the new substrate and fixed thereto.

Using this method, it is possible to transfer, per stamping procedure, for example, a plurality of GaN transistors from a first semiconductor wafer to a second semiconductor wafer, wherein the semiconductor wafers may differ in type of material, crystal orientation, wafer diameter and wafer thickness. After transfer printing, for example, insulating layers as well as conductive layers can be deposited all over the wafer and then structured in further semiconductor-process processing steps. The processing on the basis of a complete semiconductor wafer enables a cost-effective manufacture due to the parallel processing of a plurality of circuits in the same processing step. For example, transferred GaN transistors with high mobility can be covered with an insulating layer which is then structured with vias and wired to a metallization layer or metal layer.

U.S. Pat. No. 7,932,123 B2 illustrates methods according to which the functional structures are made “printable” by a plurality of so-called “release layers”.

U.S. Pat. No. 7,943,491 B2 and US 2013/0069275 A1 describe a controlled method in which the adhesion forces occurring between a component to be transferred and the transfer stamp are changed by means of the separation rate in order to temporarily attach the components to be transferred to the stamp, and to then finally fix them to the receiving substrate. In the case of a fast separation, high adhesion forces are created so that the components are temporarily attached to the stamp and released from the donor substrate, wherein the components can again be released from the stamp by use of low separation rates and thus low adhesion forces.

U.S. Pat. No. 7,799,699 B2 describes the etching free of AlGaN/GaN hetero-structure components on (111) silicon. By suitable masking and vertical plasma etching (inductively coupled plasma), exposed, i.e. unmasked trenches are etched next to the component. In the horizontal direction, the components are etched free by etching the silicon substrate beneath the component with tetramethylammonium hydroxide (THAH). Mechanical fixing in the horizontal direction is achieved by suitable interruptions of the trenches, i.e. by material bridges which are not etched away.

Thus, known methods are available for efficiently transferring components produced on a carrier substrate to a further substrate for further processing. Since usually semiconductor materials and/or process technologies and/or geometries and/or component architectures and the like are to be used in the manufacture of the components on the carrier substrate which can hardly be realized or only with very great efforts on the receiving substrate, the manufacture of the components to be transferred on the carrier substrate can usually be carried out with less effort, but nevertheless involves certain restrictions to be considered. For example, due to cost efficiency, an approved carrier material is usually used for producing the desired components to be transferred thereon. Silicon, which is one of the most frequently used substrate materials for the manufacture of electronic circuits, mechanical arrangements and the like has proven to be a suitable material. However, when producing components which generally require a different semiconductor material, for example a material with increased charge carrier mobility, a corresponding semiconductor material is to be initially produced on the silicon base material. Owing to the substantially different lattice constants of, for example, gallium nitride which, due to the substantially higher charge carrier mobility thereof (wurtzite structure with lattice constant a=0.3189 nm and c=0.5185 nm) as compared to silicon (lattice constant a=0.543 nm), is a frequently used base material, undesired mechanical stresses and the formation of disadvantageous crystal defects may typically occur during epitaxial growth (i.e. epitaxial deposition of gallium nitride on silicon) when using a (111) surface. Thus, a great number of solutions have been proposed for efficiently producing components to be produced on the basis of non-silicon materials on the approved silicon carrier material.

In this respect, U.S. Pat. No. 9,093,271 B2 describes intermediate layers made of AlN located between GaN and, if applicable, (111) silicon. Further intermediate layers made of B_{w}AlₓGa_{y}In₂N are also stated in this document.

EP 884 767 A2 shows an epitaxial method for applying GaN to (100) silicon, wherein suitable intermediate layers made of AlAs are also provided.

WO 2005/073045 A2 describes intermediate layers made of zirconium diboride (ZrB₂) for epitaxial growth of nitrides in the form of materials having a large band gap, inter alia, on (111) silicon.

U.S. Pat. No. 8,722,526 B2 describes a method for applying GaN to porous silicon by epitaxial growth for achieving an improved distribution of mechanical stresses due to the larger surface.

WO 2005/043604 A2 describes a further approach for reducing mechanical stresses in the epitaxial growth of gallium nitride on (111) silicon. A selective epitaxial growth is proposed in which deposition parameters are set such that a substantial deposition, i.e. growth of GaN, is achieved on a (111) silicon surface, whereas no material is deposited on a dielectric surface, such as a silicon nitride layer. The GaN material is thus grown on the surface of the silicon material only, while the surface areas covered with silicon nitride do not give rise to any material deposition.

U.S. Pat. No. 7,049,201 B2 describes a similar method. A selective epitaxial growth is performed in an opening through a number of insulating layers on an active region. This opening is smaller than the entire active area of the region which is, in turn, delimited by shallow trench isolation regions.

U.S. Pat. No. 4,381,202 A, U.S. Pat. No. 5,304,834 A and U.S. Pat. No. 3,421,055 A disclose selective epitaxial methods including an oxide opening.

EP 250 171 B1 describes the integration of GaAs-NESFETs in a silicon MOSFET process. In this process, the silicon MOSFET is processed up to the deposition of the intermediate-layer dielectric (ILD), i.e. up to prior to the forming of contact openings. Then, silicon dioxide and silicon nitride are applied as protective layers by chemical vapor deposition(s) and openings are etched into these protective layers in the later epitaxial region. GaAs epitaxial growth occurs over the entire wafer, however, monocrystalline growth of the GaAs material occurs on the exposed silicon surfaces only, whereas polycrystalline growth occurs on the exposed nitride protective layer. By subsequent etching away the polycrystalline GaAs, the GaAs transistor can then be finally processed subsequently thereto.

As described above, a person skilled in the art knows numerous methods for producing efficient component structures on a carrier substrate from the prior art, and there are also methods for transferring such structures to a receiving substrate, however, the required effort is relatively great in said methods, since corresponding lithography steps are required, for example, for etching free the components produced on the carrier substrate. Also for the epitaxially produced components on the carrier substrate, a series of process steps are required which, in combination with the aforementioned known process technologies, lead to a great number and an increased complexity of the process steps ultimately required for transferring the externally produced components.

### SUMMARY OF INVENTION

It is thus an object of the invention(s) to generally reduce the number of the required process steps and thus the required effort in the manufacture of components structures on a carrier substrate for providing the component structures in a state in which they can be transferred (or are transferable) to a further substrate by transfer printing.

According to one invention, the aforementioned technical problem is solved by a method for producing component structures to be transferred on a carrier substrate. The method (claim 1) comprises providing a carrier substrate including a semiconductor material with a selected crystal orientation, and producing an active region having an exposed semiconductor surface. This region is almost completely delimited by dielectric regions. Furthermore, a semiconductor structure to be transferred is formed by depositing at least one semiconductor layer on the active region by selective epitaxial growth. At least a part of the dielectric material is removed and etching is performed for removing semiconductor material beneath the semiconductor structure.

According to the invention, the active region having an exposed semiconductor surface, which serves as a target for selective epitaxial growth, is defined by dielectric regions, i.e. isolation regions so that a precise selection of substrate regions, on which the further semiconductor material(s) are grown in the subsequent process, is carried out already by the production of the dielectric regions, i.e. the isolation regions.

Thus, the epitaxial growth of the semiconductor material for the semiconductor structures to be transferred can be carried out in small regions so that the generation of stresses, which typically occur due to the different lattice constants, is kept low. Thus, the lateral size and shape of the later semiconductor structure is defined by the dielectric regions. In other word, the dielectric regions define the size and shape of the active regions and delimit the same at least in an almost complete manner. In this connection, the expression “delimit in an almost complete manner” is to be understood such that small regions, which can be used as connection elements in the further process, can be recessed in the production of the dielectric regions, i.e. the dielectric regions can be interrupted by semiconductor material of the carrier substrate, which regions provide for low mechanical coupling to the carrier substrate after epitaxial growth of the desired semiconductor materials.

Thus, also the lateral shape of the semiconductor structure is substantially defined by the dielectric regions, wherein no further etching free is required after epitaxial growth of the semiconductor material(s) for the semiconductor structure due to the lack of deposition of semiconductor material of the semiconductor structure on the dielectric regions. Then, access to the underlying semiconductor material of the carrier substrate is provided by the at least partial removal of the dielectric material from the dielectric regions, wherein this is also possible without further masking processes, since, for example, a selective etching can be employed for selectively removing the dielectric material with respect to the previously deposited semiconductor materials of the semiconductor structure. The further semiconductor material can then be removed by etching beneath the previously produced semiconductor structure via the lateral access to the semiconductor material of the carrier substrate. In sum, a substantially reduced complexity of the entire manufacturing process for the semiconductor structure is achieved (obtained, created, accomplished or “ensured”) in this way. This is accomplished by a reduction of masking steps, an efficient manufacture of desired semiconductor structures which, if required, may be processed still further prior to transferring them to a receiving substrate.

In one embodiment, the dielectric regions are formed by local oxidation of the semiconductor material of the carrier substrate. The local oxidation of the carrier substrate, which is provided, for example, in the form of silicon, is an approved technique in which oxidized regions can be precisely created which penetrate the semiconductor surface of the carrier substrate to a certain degree and thus create dielectric regions, the lower interface of which is located deeper than the surface of the adjacent active region, i.e. the surface of the semiconductor material of the carrier substrate. When at least a part of the oxide material of the dielectric regions is removed, if they are produced by local oxidation, access for undercutting is provided after production of the semiconductor structure on the exposed surface of the carrier substrate in the active region.

In a further advantageous embodiment, the dielectric regions are formed as trench isolation regions. This process technology is well known per se and allows the precise creation of regions which can be filled with a suitable dielectric material, for example, oxide and/or nitride. In the process, a relatively planar surface is created so that the prerequisites for the further processing are created, for example, the selective deposition of one or more desired semiconductor materials, wherein the further processing thereof can be carried out on the basis of a topography almost unaffected by the dielectric regions. Furthermore, a high degree of flexibility is achieved in the selection of the dielectric material which can be provided as the last surface in order to thus achieve a high selectivity in the subsequent selective epitaxial growth. For example, silicon nitride is a well-known material for which highly selective deposition recipes are known for the metal-organic chemical vapor deposition (MOCVD) for epitaxial growth of various III/V materials. Moreover, by the removal of at least a part of the dielectric material of the isolation structures, lateral areas of the original semiconductor material of carrier substrate can be efficiently exposed without further masking steps so that a lateral etching attack for undercutting the previously applied semiconductor structure is possible.

In one embodiment, the at least one semiconductor layer comprises a III/V semiconductor material. As already mentioned above, by the use of a III/V semiconductor material, for example, a higher electron mobility can be achieved as compared to germanium or silicon so that more efficient components, such as transistors, can be produced.

In a further variant, further process steps are performed on the semiconductor structure for forming at least one component to be transferred. In this embodiment, further process steps, as used, for example, for the production of transistors, are performed so that only a few further process steps are required in the receiving substrate after transfer of the semiconductor structure. This can be advantageous when the process steps performed on the semiconductor structure would otherwise lead to unsuitable process conditions in the receiving substrate, such as high temperatures, etc., which would be incompatible with the further manufacturing process on the receiving substrate. In other variants, the semiconductor structure can be transferred without or only with a moderate degree of processing when the further processing is compatible with the process steps on the receiving substrate.

In one variant, the component to be transferred is, for example, a transistor with high electron mobility.

In a further advantageous embodiment, the carrier substrate is provided in the form of a substrate including a buried dielectric layer, such as a buried oxide layer, on which the semiconductor material of the carrier substrate is formed. Thus, a higher degree of flexibility is achieved in the manufacture of the semiconductor structure, for example, with respect to the material consumption of the carrier substrate and the like.

In an advantageous embodiment, the etching for removing semiconductor material beneath the semiconductor structure is carried out by performing an anisotropic etching in which a lateral etching rate is higher than a vertical etching rate. In this way, the material consumption of the carrier substrate is kept relatively low. For example, a great number of anisotropic etching recipes, for example for silicon material, are available which have highly different etching rates in the different crystal directions.

In this respect, it is helpful that position information or the indication of directions is generally to be understood in terms of the substrate and not as absolute position information. For this purpose, the surface of the carrier substrate serves as a reference. Thus, a first element or a first layer is located “beneath” a second element or a second layer when the distance of the first element or the first layer from the surface of the carrier substrate in the direction into the substrate is larger than the distance of the second element or the second layer to the surface of the carrier substrate. The same applies to the term “above”. In this connection, lateral or at the side is to be understood as a direction extending substantially parallel to the surface of the carrier substrate. Similarly, terms such as vertical and horizontal are always to be understood in terms of the carrier substrate.

In a further embodiment, the etching for removing semiconductor material beneath the semiconductor structure is carried out by performing an isotropic etching, wherein especially a carrier substrate with a buried dielectric layer is used here. By the use of the dielectric layer as an etching stop layer, the material removal and the vertical extension of the etching can thus be kept low so that a variety of suitable etching recipes can be applied for enabling a vertical release of the semiconductor structure from the material of the carrier substrate.

In a further advantageous embodiment, the semiconductor structure is released from the carrier substrate by performing a transfer printing process. In other words, the efficient etching free of the semiconductor structure from the carrier substrate without the need for complex masked etching steps allows an efficient execution of the transfer process.

According to a further invention, the aforementioned technical object is achieved by a carrier substrate (claim 13) including semiconductor structures to be transferred. The carrier substrate according to the invention, which represents a unit, circuit, or device corresponding to a certain manufacturing stage of the abovementioned method, comprises an isolation structure, which is formed in a semiconductor material of the carrier substrate and laterally delimits an active region of the semiconductor material. The isolation structure is to be understood such that it has a suitable geometrical shape and is filled with a dielectric material so that a dielectric region for delimiting the active region is provided.

Also here it applies that small, i.e. small-area interruptions of the isolation structure may present for providing one or more connection elements, if required.

The carrier substrate according to the invention further comprises a III/V semiconductor structure which is formed on the active region and leaves the isolation structure blank. In other words, the semiconductor structure is not formed on the isolation structure.

As already explained before, by this arrangement of the carrier substrate, the possibility arises to precisely design the lateral extension of the component structure, on the one hand, and to create the prerequisites for undercutting the semiconductor structure without further masking steps, i.e. especially without a further lithography process, on the other hand, for creating the prerequisites for the subsequent transfer of the semiconductor structure.

In one embodiment, the isolation structure is produced by local oxidation, whereas the isolation structure is a trench isolation structure in another embodiment. The advantages of the two variants have already been explained above. Furthermore, in one variant, the semiconductor structure comprises at least one gallium-nitride containing transistor with high electron mobility. As also explained above, the strategy according to the invention allows the construction of the semiconductor structure with reduced effort so that especially transistors with high electron mobility can be efficiently produced on the basis of gallium nitride and efficiently transferred to a further substrate, such as a substrate with CMOS components, so that, all in all, high-performance integrated circuits can be provided with reduced effort. In one variant, the carrier substrate comprises a buried dielectric layer beneath the semiconductor structure.

As explained above, a higher degree of flexibility arises therefrom for bringing the semiconductor structure in a state in which it can be released from the carrier substrate.

### INTRODUCTION TO THE DRAWINGS

Embodiments of the invention are illustrated by means of examples and not in a way that transfers or incorporates limitations from the Figures into the patent claims. Same reference numerals in the Figures indicate same or similar elements.

FIG. 1 shows a carrier substrate 10 in the form of a silicon substrate wafer including an oxide layer 12 applied thereto or produced thereon, and a silicon nitride layer 14. Silicon is an example of a semiconductor.

FIG. 2 shows the carrier substrate 10 with openings 20 etched into the silicon nitride layer 14.

FIG. 3 shows the carrier substrate 10 with an isolation structure, especially dielectric regions in the form of field oxide bridges 30 produced by local oxidation.

FIG. 4 shows the carrier substrate 10 with the dielectric regions 30 and a selectively grown stack (or structure) 40 of semiconductor materials.

FIG. 5 shows the carrier substrate with completely processed III/V components 52 and trenches 50 in the adjacent semiconductor material of the carrier substrate after removal of the dielectric regions 30.

FIG. 6 shows the carrier substrate with a completely processed III/V component 52 and an undercut 60 produced in certain areas of a respective component 52.

FIG. 7 shows the carrier substrate with completely processed III/V components 52 and a completed undercut 70 (without connection elements) for each component 52.

FIG. 8 shows the carrier substrate according to a further embodiment in which isolation structures or dielectric regions for delimiting the active region 11 are provided in the form of trench isolation structures 80, e.g. shallow trench isolation regions.

FIG. 9 shows the carrier substrate with the trench isolation regions 80 and a selectively grown epitaxial layer stack 40.

FIG. 10 shows the carrier substrate with completely processed III/V components 52 and trenches 100 formed in the adjacent semiconductor material of the carrier substrate.

FIG. 11 shows the carrier substrate with the completely processed III/V components 52 and the produced partial undercuts 110.

FIG. 12 shows the carrier substrate with the completely processed III/V components and the produced complete undercuts 120.

### DETAILED DESCRIPTION OF THE DRAWINGS

Embodiments will be explained in greater detail with reference to the Figures.

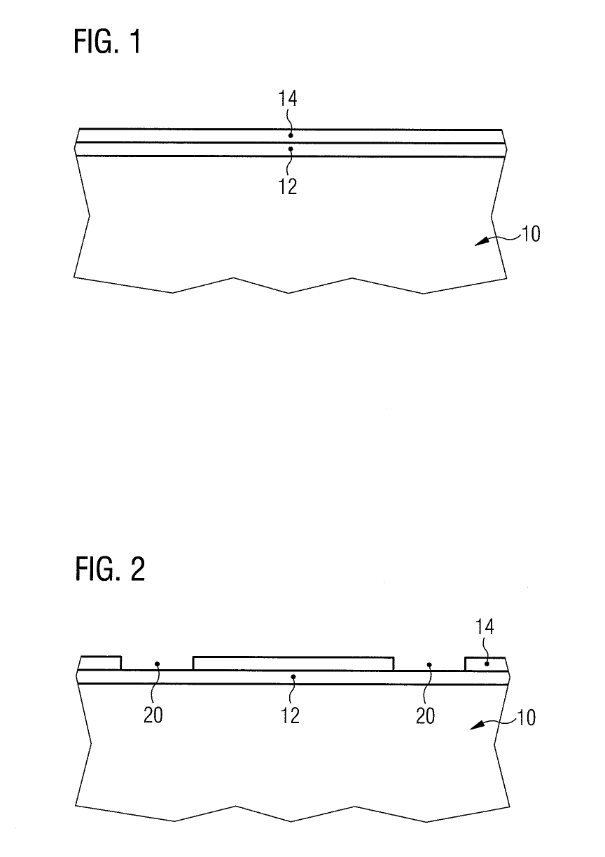

FIG. 1 shows a carrier substrate 10 having a crystal orientation suitable for the subsequent selective epitaxial growth. The semiconductor carrier substrate 10 is provided, for example, in the form of a silicon substrate having a (111) surface orientation so that, for example, gallium nitride can be grown thereon.

However, it is to be noted that other crystal orientations and/or other semiconductor materials can be used for the carrier substrate 10. Furthermore, in other embodiments, a buried dielectric layer (not shown) is provided which comprises a semiconductor layer, e.g. a silicon layer, formed thereon with a defined thickness, which thus forms the semiconductor material of the carrier substrate 10 for the subsequent selective epitaxial growth.

Corresponding substrates with a buried dielectric layer, for example a buried oxide, can be obtained from manufacturers, or can be produced from a bulk substrate during processing.

A buried dielectric layer can also be produced locally on the substrate 10.

In the shown production stage, the carrier substrate 10 comprises an oxide layer 12, to which a silicon nitride layer 14 is applied. The oxide layer 12 can be produced by thermal oxidation, by deposition, etc. The nitride layer 14 is produced, for example, by a chemical vapor deposition (CVD) method which is known to a person skilled in the art.

FIG. 2 shows the carrier substrate 10 with openings 20 formed in the nitride layer 14 so that the underlying oxide layer 12 is exposed. The openings 20 can be produced by known method steps including photolithography and etching. Thus, the lateral dimensions and the geometry of dielectric regions or an isolation structure, which is to be formed subsequently in the semiconductor material of the carrier substrate 10, are substantially defined.

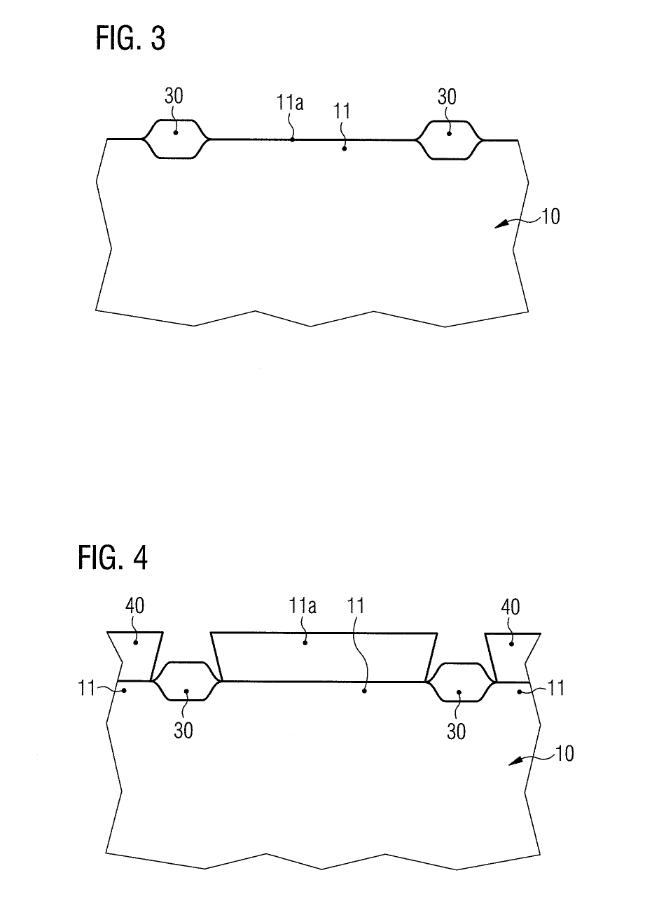

FIG. 3 shows the carrier substrate 10 in a further advanced production phase, wherein an isolation structure, for example in the form of dielectric regions 30, has been produced which delimits an active region 11 including an exposed semiconductor surface. In this phase, the active region 11 is shown in a state already freed of contaminants and other layers, e.g. a natural oxide, in order to be prepared for a subsequent selective epitaxial growth.

The structure shown in FIG. 3 can be produced by an oxidation process which results in the production of the dielectric regions 30, which are also referred to as isolation structure herein, wherein, due to the increase in volume, the resulting oxide material grows into the semiconductor material of the carrier substrate 10 and also forms a corresponding elevation. Nevertheless, due to the oxidation process, it is achieved that a lower area of the dielectric regions 30 (which is the lowest interface between the semiconductor material and the oxide material of the dielectric regions 30) is located below the exposed surface 110 of the active region 11.

The isolation structure in the form of the dielectric regions 30 can be interrupted in suitable positions so that bridges or portions remain there in the semiconductor material which, in a later stage after epitaxial growth of a semiconductor material, serve as connection elements for horizontal fixing prior to transfer.

FIG. 4 shows the carrier substrate 10 in a yet further advanced production phase, wherein a selectively epitaxially grown semiconductor structure 40 is formed on exposed active regions 11, cf. FIG. 3.

For example, the semiconductor structure 40 can comprise a plurality of epitaxially grown III/V layers. A sequence of AlN/AlGaN/GaN can be provided for obtaining a transition as stress-free as possible in the semiconductor structure 40 from the base material of the carrier substrate 10 to the topmost layer of the structure 40.

As explained above, a selective epitaxial growth, e.g. MOCVD, is used in which the deposition on the dielectric regions 30 is almost zero so that the dielectric regions 30 are accessible for the further processing without further process steps and horizontal etching free is not required.

In advantageous embodiments, further process steps are carried out on the structure shown in FIG. 4 for creating the desired III/V components 52, for example, transistors with high electron mobility, for example, from the semiconductor structure 40. The processing or execution of at least some process steps for the further structuring and production of the desired components 52 on the carrier substrate 10 can be advantageous when these process steps would require increased efforts in the receiving substrate, in which other components are produced or are to be produced, or would generally be incompatible with the techniques and materials employed therein.

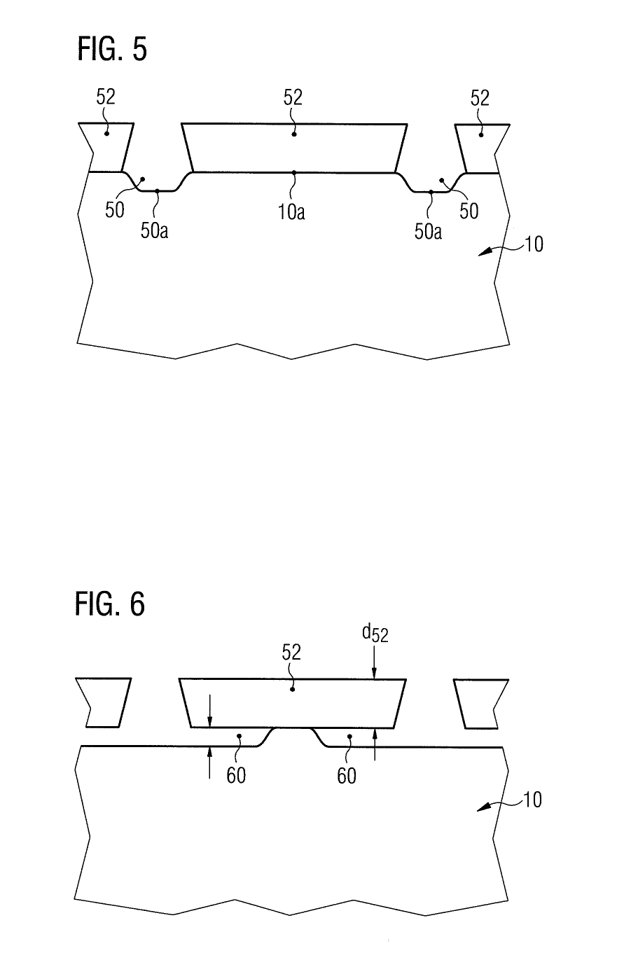

FIG. 5 schematically shows the carrier substrate 10 in a still further advanced production phase in which, for example, the III/V components 52 are provided. Furthermore, the dielectric material of the isolation structure or dielectric regions 30 has been removed at least in parts so that respective trenches 50 are formed in their place, the bottoms 50a of which are located deeper than the surface 10a of the semiconductor material of the carrier substrate 10.

In the shown embodiment, each trench 50 is formed such that substantially the entire dielectric material 30 is removed. In other variants, etching is performed up to a depth only, at which the semiconductor material of the carrier substrate 10 is laterally exposed.

The removal of the material 30 for forming the trench 50 is carried out, for example, by applying selective etching recipes in which the dielectric material is selectively removed with respect to the surrounding semiconductor material. Suitable recipes are obtainable from the prior art to this effect. Thus, it is to be pointed out that masking of the structure is not required for producing the trenches 50 in advantageous embodiments.

FIG. 6 shows the carrier substrate 10 with the semiconductor structure, especially the III/V components 52, when further processing steps have been carried out before. In the shown phase, a partial undercut 60 has already been formed so that a substantial (lateral) part of the material of the carrier substrate 10 beneath the III/V component 52 has been removed. In an advantageous embodiment, the corresponding etching recipe is selected such that a lateral (here horizontal) etching rate is substantially greater or higher than a vertical etching rate.

For example, etchants are available having substantially different etching rates for different crystal orientations. Such an etchant is, for example, TMAH, as described above. It is particularly suited for the etching of silicon, wherein a considerably smaller etching rate occurs in the <111> direction than in the other crystal directions.

In the shown embodiment, the <111> direction is roughly the vertical direction.

In other embodiments, isotropic etching recipes can be employed when the vertical material removal in the carrier substrate 10 is acceptable. In further embodiments, a not shown dielectric layer is provided as a buried layer in the substrate 10, wherein this buried dielectric layer serves as an etching stop layer in order to thus exactly delimit a vertical extension of the etching when applying an isotropic etching recipe. Thus, the corresponding carrier substrate 10 can be employed again for further intended uses.

The depth of the undercut 60 is in the order of the thickness d₅₂ of the components 52, i.e. is not greater than, for example, three times the thickness d₅₂. t₆₀ is thus less than 3*d₅₂, i.e. can be less than d₅₂, but not much greater, here having an upper limit of three times d₅₂. In other embodiments, the thickness of the semiconductor material of the carrier substrate 10 is the measure, wherein the depth t₆₀ is less than the thickness of the substrate 10.

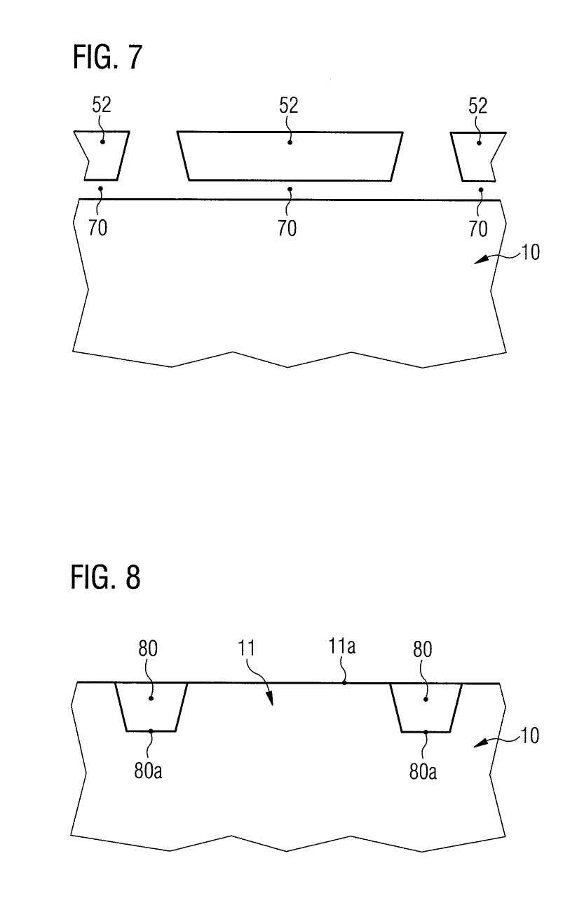

FIG. 7 shows the carrier substrate 10 in a state in which the III/V component(s) 52 are completely undercut and thus completely released from the material of the carrier substrate 10. The shown undercut 70 thus releases the respective component 52 from the carrier substrate 10 in the vertical direction. As explained above, due to the isolation structures etched at least in part before, the component(s) 52 are released from each other also in the horizontal direction, wherein corresponding individual connection elements may be provided, which are not shown here, for maintaining a certain mechanical connection to the carrier substrate 10 prior to the transfer of individual semiconductor structures by use of a stamp. During etching for producing the undercuts 70, the carrier material of the connection elements is also etched away, and the semiconductor material deposited thereon provides for the mechanical connection.

In the shown state, any suitable method can be used for making contact with a transfer stamp for adhering at least some of the components 52, which are extensively formed on the carrier substrate 10, to the stamp, and for releasing them from the carrier substrate 10 by fracturing or separating the not shown connection elements. Subsequently, the adhering components 52 can be applied to suitable positions in one or more receiving substrate(s).

Further embodiments will be described with reference to FIGS. 8 to 12. Elements and components similar or identical to the elements and components of the previous Figures are denoted by same reference numerals, and the corresponding description of these elements and components as well as of the manufacture thereof is at least shortened.

FIG. 8 shows the carrier substrate 10 having the suitable crystal orientation, as explained above. Furthermore, an isolation structure 80 is formed in the semiconductor material of the carrier substrate 10, which delimits the active region 11 accordingly, wherein regions for connection elements may interrupt the isolation structure 80, if required, as explained above with reference to the isolation structure 30.

The isolation structure 80 is thus provided as a trench isolation structure which can be produced by known steps and techniques, including photolithography, trench etching, oxide deposition (also thermal oxide formation) and/or deposition of a different or further dielectric material, e.g. silicon nitride.

The isolation structure 80 is finalized as illustrated by means of a subsequent planarization of the surface, e.g. by chemical mechanical polishing (CMP). As explained above, two or more dielectric materials can be provided for the structure 80 for obtaining a surface suitable for the subsequent selective epitaxial deposition, if necessary. Also in this case, it is clearly apparent that a lower interface 80a between the isolation structure 80 and the semiconductor material of the carrier substrate 10 is located substantially deeper than a surface 111 of the active region 11 between the isolation structures 80.

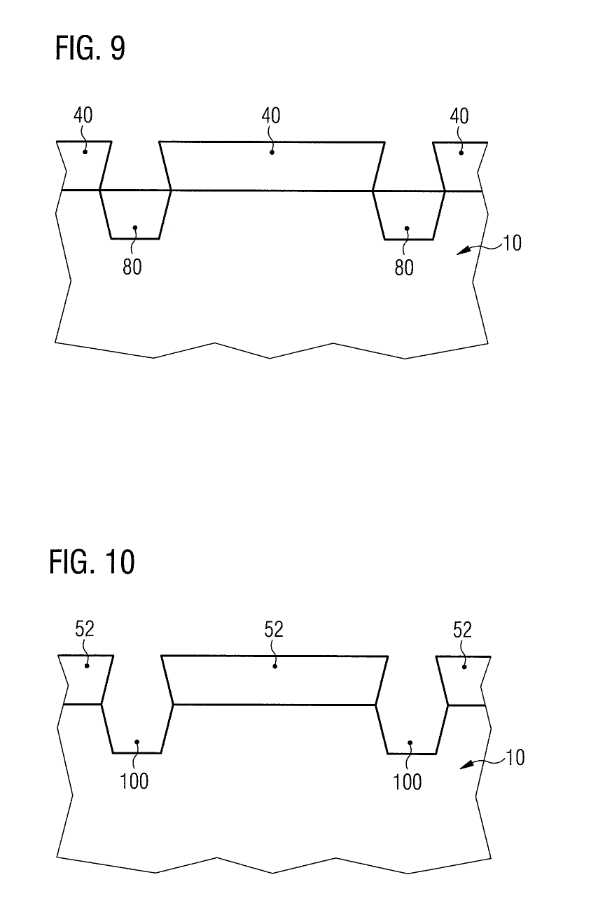

FIG. 9 shows the carrier substrate 10 in a further advanced phase in which the semiconductor structure 40 has been formed which, in turn, comprises at least one semiconductor layer differing from the semiconductor material of the carrier substrate 10 in at least one property.

As explained above, the semiconductor structure 40 may comprise a plurality of semiconductor layers. Due to the surface properties of the isolation structure 80, deposition on the structure 80 is substantially suppressed, as explained above. Moreover, in case a higher degree of processing of the semiconductor structure 40 is desired, further processing steps can be performed prior to transferring it to a receiving substrate.

FIG. 10 shows the carrier substrate 10 with one or more processed III/V components 52. The criteria explained above also apply to the component(s) 52. Moreover, the dielectric material (as a dielectrically isolating material) of the isolation structure 80, cf. FIG. 9, has been removed at least in part so that one or more trenches 100 are provided in the semiconductor material of the carrier substrate 10. Thus, a person skilled in the art is provided with a lateral access to the semiconductor material of the substrate 10 beneath the component 52.

In the shown variant, the dielectric material of the isolation structure 80 according to FIG. 9 has been completely removed. As explained above, this is achieved by a selective etching step so that an additional photolithography step is not required here either in advantageous embodiments.

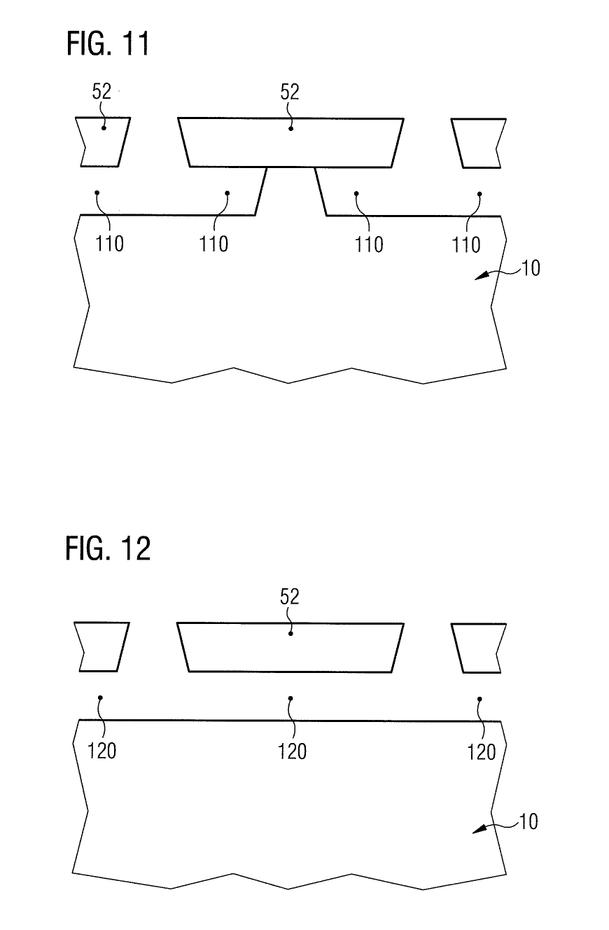

FIG. 11 shows the carrier substrate 10 in an advanced stage in which a partial undercutting 110 has been carried out beneath each one of the components 52. For this purpose, anisotropic etching recipes can again be employed, as described above. In other embodiments, isotropic etching recipes are employed when the vertical etching depth is irrelevant. As explained above, a buried dielectric layer can also be provided as an etching stop layer.

FIG. 12 shows the carrier substrate 10 in a state in which a complete undercutting 120 of each one of the components 52 has been carried out so that the component(s) 52 are released from the carrier substrate 10 in the vertical direction. Also in the horizontal direction, release thereof is provided due to the selective epitaxial growth, wherein corresponding connection elements (not shown) may still be provided for maintaining a mechanical fixing of the components 52 to the carrier substrate 10 until the components 52 are released.

The examples enable an efficient manufacture of semiconductor structures which are grown on a suitable carrier substrate and processed up to a desired degree of manufacture, wherein a reduction of the mechanical stresses is achieved by selective epitaxial growth, except for possible connection elements. The lateral shaping (the actual growth region) for the selective epitaxial growth is defined by isolation structures which, due to their surface properties, prevent a deposition of the semiconductor materials to be grown. By later removal of dielectric material from these isolation structures, access for the lateral etching attack for undercutting the semiconductor structure(s) is provided, which can be accomplished without an additional lithography process. Thus, the manufacture of arbitrarily processed semiconductor structures on a carrier substrate is substantially simplified as compared to conventional strategies so that a considerable advantage with respect to time and cost is obtained.

1. A method for producing semiconductor structures to be transferred on a carrier substrate, the method comprising:
providing a carrier substrate (10) including a semiconductor material with a selected crystal orientation;
producing an active region (11) which has an exposed semiconductor surface (11) and is almost completely delimited by dielectric regions (30, 80) including an isolating dielectric material;
forming a semiconductor structure (40) to be transferred by depositing at least one semiconductor layer on the active region (11);
removing at least a portion of the dielectric material;
performing an etching (60, 70, 110, 120) for removing semiconductor material beneath the semiconductor structure (40) to be transferred.

2. The method according to claim 1, wherein the dielectric regions (30) are formed by local oxidation of the semiconductor material of the carrier substrate (10).

3. The method according to claim 1, wherein the dielectric regions (80) are formed as trench isolation regions.

4. The method according to claim 1, wherein the at least one semiconductor layer (40) is or comprises a III/V semiconductor material.

5. The method according to claim 4, wherein the III/V semiconductor material is or comprises a gallium nitride.

6. The method according to claim 1, wherein further process steps are performed on the semiconductor structure (40) to be transferred for forming at least one component (52) to be transferred.

7. The method according to claim 6, wherein the at least one component (52) to be transferred is or comprises a transistor with at least good electron mobility.

8. The method according to claim 1, wherein providing the carrier substrate (10) comprises: providing the carrier substrate including a buried dielectric layer on which the semiconductor material rests.

9. The method according to claim 1, wherein performing the etching (60) for removing semiconductor material beneath the semiconductor structure (40) comprises an anisotropic etching in which a lateral etching rate is higher than a vertical etching rate.

10. The method according to claim 1, wherein performing the etching (60, 70, 110) for removing semiconductor material beneath the semiconductor structure (40) comprises an isotropic etching.

11. The method according to claim 1, further comprising releasing the semiconductor structure (40) from the carrier substrate and performing a transfer printing process.

12. The method according to claim 1, wherein forming the semiconductor structure (40) to be transferred is carried out by a selective epitaxial growth.

13. The method according to claim 1 being performed in the stated order of the method steps.

14. The method according to claim 1, wherein the etching is an undercutting (60, 70, 110, 120) with a depth extension of less than three times a thickness of the semiconductor structure (40).

15. The method according to claim 6, wherein a depth extension of the etching for removing the semiconductor material beneath the component (52) is less than one thickness of the carrier substrate (10).

16. The method according to claim 15, wherein the depth extension of the etching is in the order of the thickness of the component (52).

17. The method according to claim 15, wherein the depth extension of the etching is less than three times the thickness of the component.

18. A carrier substrate including semiconductor structures to be transferred, the carrier substrate comprising:
an isolation structure (30, 80) which is formed in a semiconductor material of the carrier substrate (10) and laterally delimits an active region (11) of the semiconductor material;
a III/V semiconductor structure (40) which is formed on the active region (11) and leaves the isolation structure (30, 80) blank.

19. The carrier substrate according to claim 18, wherein the isolation structure is a trench isolation structure (80).

20. The carrier substrate according to claim 18, wherein the III/V semiconductor structure (40) comprise at least one gallium-nitride containing transistor with at least good electron mobility.

21. The carrier substrate according to claim 18, further comprising a buried dielectric layer beneath the III/V semiconductor structure (40).

22. The carrier substrate according to claim 18, wherein the isolation structure is an isolation structure producible or produced by local oxidation.
